(19) United States
(12) Patent Application Publication
(10) Pub. No.: US 2004/0103359 A1
(43) Pub. Date: May 27, 2004

(54) Dynamic real time generation of 3GPP turbo decoder interleaver sequence

(76) Inventor: Robert Jose Molina, Austin, TX (US)

Correspondence Address: Randi L. Dulaney, Motorola, Inc., Law Department, 8000 West Sunrise Boulevard, Fort Lauderdale, FL, 33322, US

(21) Appl. No.: 10/306,071

(22) Filed: Nov. 27, 2002

(51) Int. Cl. H03M 13/00; G11C 29/00

(52) U.S. Cl. 714/763

(57) ABSTRACT

An apparatus for dynamic real time generation of interleaver sequences for a decoder includes a vector memory (210) that stores a plurality of vectors (212, 214, 216). Each vector (212, 214, 216) corresponds to a desired reordering of a matrix. A data memory (240) stores individual data elements (242) from a data stream (202) so that each data element (242) is stored in a different memory location in a predetermined order. An interleaver (220) circuit dynamically generates a plurality of interleaver elements (224), each in response to a request signal (226) (being asserted and each pointing to a memory location. A MAP decoder (260) receives the interleaver elements (224) from the interleaver circuit and retrieves the data element (242) stored in a memory location pointed to by each interleaver element (224). The MAP decoder (260) generates a reordered data stream (262) including the data elements (242) ordered in an arrangement corresponding to the sequence in which the interleaver elements (224) are received from the interleaver circuit.

### BACKGROUND OF THE INVENTION

1. Field of the Invention

The present invention relates to communications systems and, more specifically, for systems used to decode communications.

2. Description of the Prior Art

Turbo coding is the forward error-correction coding scheme being used in the next wireless generation (3G). It is an iterative algorithm where information is passed between two maximum a priori (MAP) decoders a prescribed number of iterations. The turbo decoder makes use of an interleaver, which is essentially a memory address permuter.

As shown in FIG. 1, as the data is passed between the two decoders it is interleaved, or jumbled in a pseudo-random order as dictated by a look-up table (LUT). For example, if the LUT was of length 5, and consisted of the sequence (4,3,2,1,0), then every group of 5 elements of data would be reversed. Thus, a data sequence (a,b,c,d,e,f,g,h,i,j,k . . . ) would become (e,d,c,b,a,j,i,h,g,f . . . ). Similarly, if the interleaver LUT consisted of the sequence (1,0,2,3,4), then the first and second element of every group of five data elements would be reversed. The above sequence would become (b,a,c,d,e,g,f,h,i,j . . . ). The algorithm for the generation of the LUT is uniform as specified by 3GPP, a consortium of companies specifying the next generation communication systems.

There are two ways these LUTs are typically generated. The most common is by storing mother interleavers. There are 5074 interleaver block sizes allowed by the 3GPP specification, ranging from 40 through 5114. These individual subsets are all subsets of a group of 224 sequences termed “mother interleavers”. Each mother interleaver produces anywhere from one to 200 interleaver sequences. They can be generated from the specification and stored in memory. When an incoming frame signals a change in interleaver size, the corresponding mother interleaver is retrieved from memory and pruned to produce the desired interleaver sequence. The problem with this method is the massive amounts of memory (over 1.1 megabytes) are necessary to store the mother interleavers. This amount of memory allocation is prohibitive for many systems (for example, hand-held devices).

Another method is to use a digital signal processor (DSP) or some other host processor to generate the interleaver indices. Since the interleaver block size can change with every incoming frame, this method puts tremendous computational pressure on the processor. It must run the algorithm in its entirety and store the results in memory before the MAP decoders can begin to operate on the data. Input/output concerns also develop, with the necessary memory access and communication with the MAP.

Therefore, there is a need for a 3GPP turbo decoder that provides interleaver indices without requiring a look-up table.

### BRIEF DESCRIPTION OF THE FIGURES OF THE DRAWINGS

FIG. 1 is a block diagram of a prior art system.

FIG. 2 is a block diagram of a system according to the invention.

FIG. 3 is a block diagram showing three stages of one embodiment of the invention.

FIG. 4 is a block diagram showing generation and use of interleaver elements.

FIG. 5 is a flowchart showing an interleaver element generation cycle.

FIG. 6 is a flowchart showing determination of number of rows.

FIG. 7 is a flowchart showing generation of a prime number sequence.

FIG. 8 is a flowchart showing determination of number of columns.

FIG. 9 is a flowchart showing generation of a c vector.

FIG. 10 is a flowchart showing generation of a q vector.

FIG. 11 is a flowchart showing generation of a P vector.

FIG. 12 is a flowchart showing generation of a p vector.

FIG. 13 is a flowchart showing determination of matrix elements.

FIG. 14 is a flowchart showing generation of a matrix.

FIG. 15 is a flowchart showing generation of an interleaver sequence for a special case.

FIG. 16 is a flowchart showing generation of interleaver element.

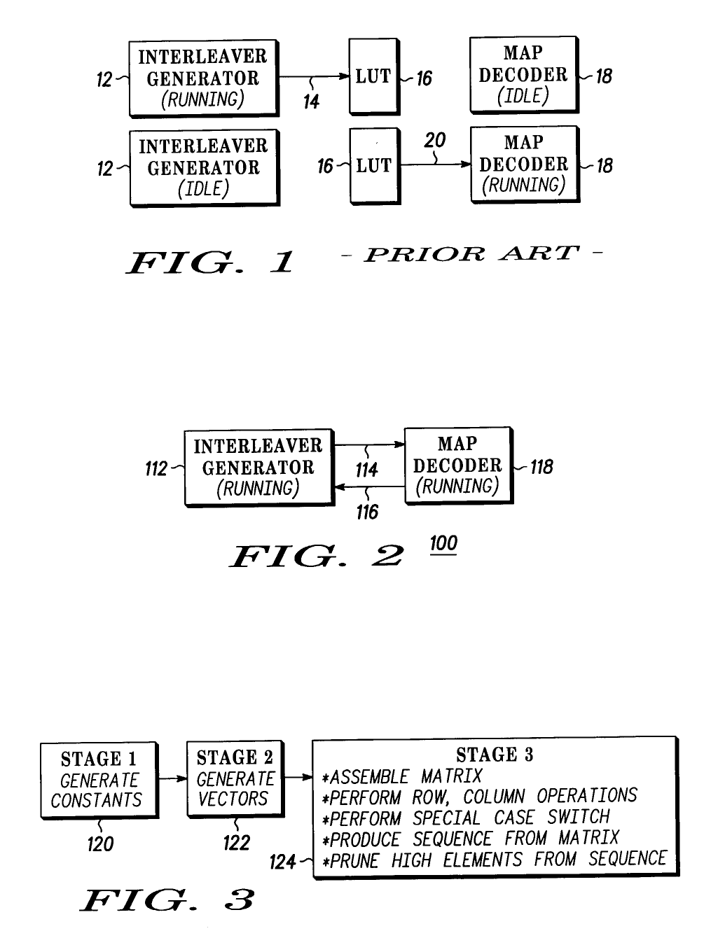

### DETAILED DESCRIPTION OF THE INVENTION

An illustrative embodiment of the invention is now described in detail. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

As shown in FIG. 2, the present invention 100 overcomes the limitations of the prior art by employing an interleaver generator 112 to generating interleaver elements dynamically as they are needed by a MAP decoder 118. The interleaver generator 112 responds to a signal 116 from the MAP decoder 118 requesting additional interleaver elements by generating new interleaver elements and adding them to a stream 114 of interleaver elements.

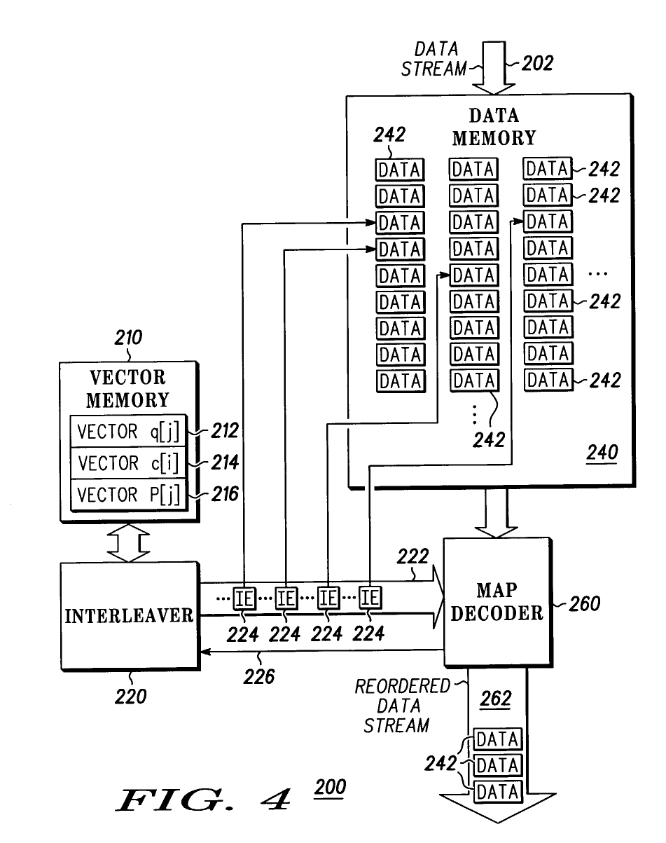

As shown in FIG. 3, setting up the interleaver generator 112 involves two pre-dynamic steps: generating a set of constants 120 and generating a set of vectors 122. Upon completion of the pre-dynamic steps, the interleaver generator 112 is capable of performing a plurality of dynamic steps 124 that result in transmission of interleaver elements to the MAP decoder 118.

One exemplary system 200 for dynamic real time generation of interleaver sequences for a 3GPP decoder is shown in FIG. 4. The system 200 includes a vector memory 210, an interleaver 220, a data memory 240 and a MAP decoder 260. The vector memory 210 stores three vectors: (1) the q[j] vector 212; (2) the c[i] vector 214; and (3) the P[j] vector 216.

Non-interleaved data, consisting of a plurality of data elements 242, is received by the data memory 240 from a data stream 202. Each data element 242 is stored in the data memory 240 according a predetermined ordering. The predetermined ordering is determined from the 3GPP specification based on the amount of data that is received.

The interleaver 220 generates a plurality of interleaver elements 224 and transmits them to the MAP decoder via a data channel 222. The interleaver 220 generates each interleaver element 224 in response to a request signal 226 received from the MAP decoder 260. Each interleaver element 224 points to a different data element 242 in the data memory 240.

When the MAP decoder receives an interleaver element 224 from the data channel 222, it fetches the data element 242 pointed to by the interleaver element 224 and transmits the data element 224 on a reordered data stream 262. The order of the data elements 242 in the reordered data stream 262 corresponds to the order that the interleaver elements 224 are received from the interleaver 220. Thus, the data 242 from the data memory 240 is reordered by the MAP decoder 260 according to the order that the interleaver elements 224 are received from the interleaver 220.

The method used is shown in FIG. 5, in which a plurality of constants and vectors are determined 302 in a pre-processing stage. During the beginning of a dynamic stage 304, matrix operations are simulated by the interleaver to produced the interleaver elements and certain special cases are accounted for. An interleaver element is then transmitted 306 to the MAP decoder. The MAP decoder uses the interleaver element to fetch a data element and then generates a request for another interleaver element 308, which is transmitted to the interleaver as a control signal 309.

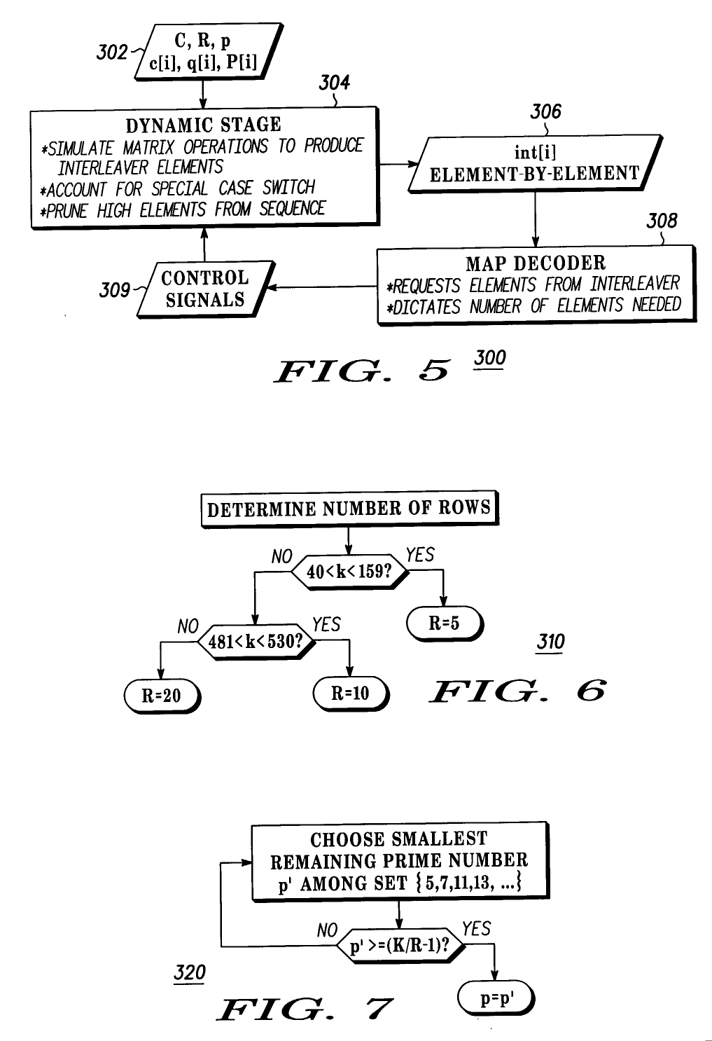

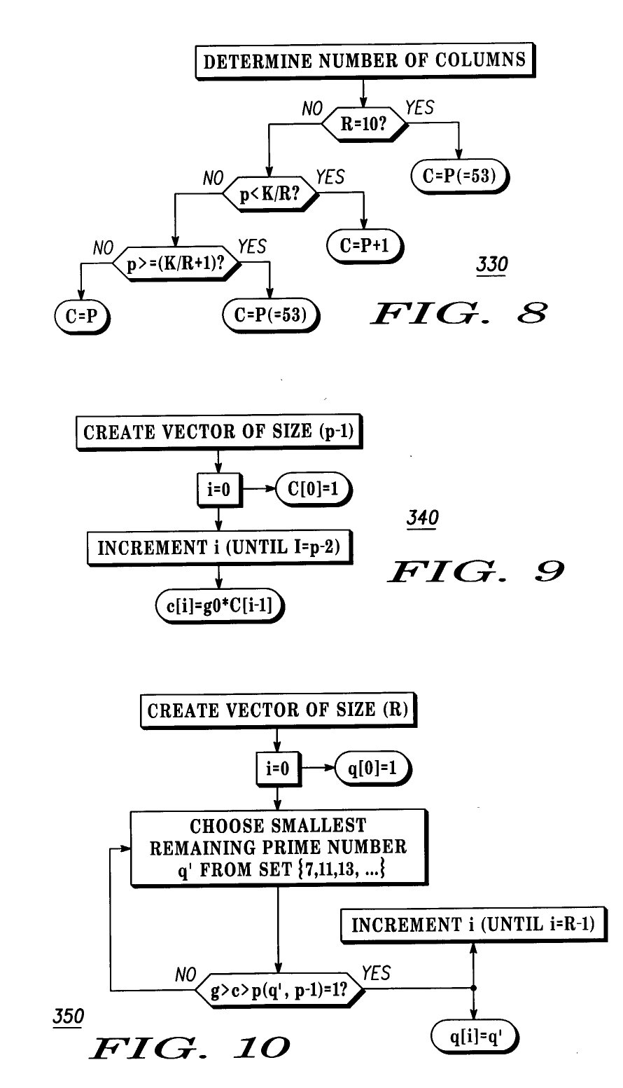

In executing step 302, the system must first determine the number of rows and columns that the data will occupy, if assembled as a matrix in the data memory. One method 310 of determining the number of rows is shown in FIG. 6. To determine the number of columns, the system must first choose a prime number according to the algorithm 320 shown in FIG. 7. Once the correct prime number is chosen, then system executes a routine 330 to determine the number of columns, as shown in FIG. 8.

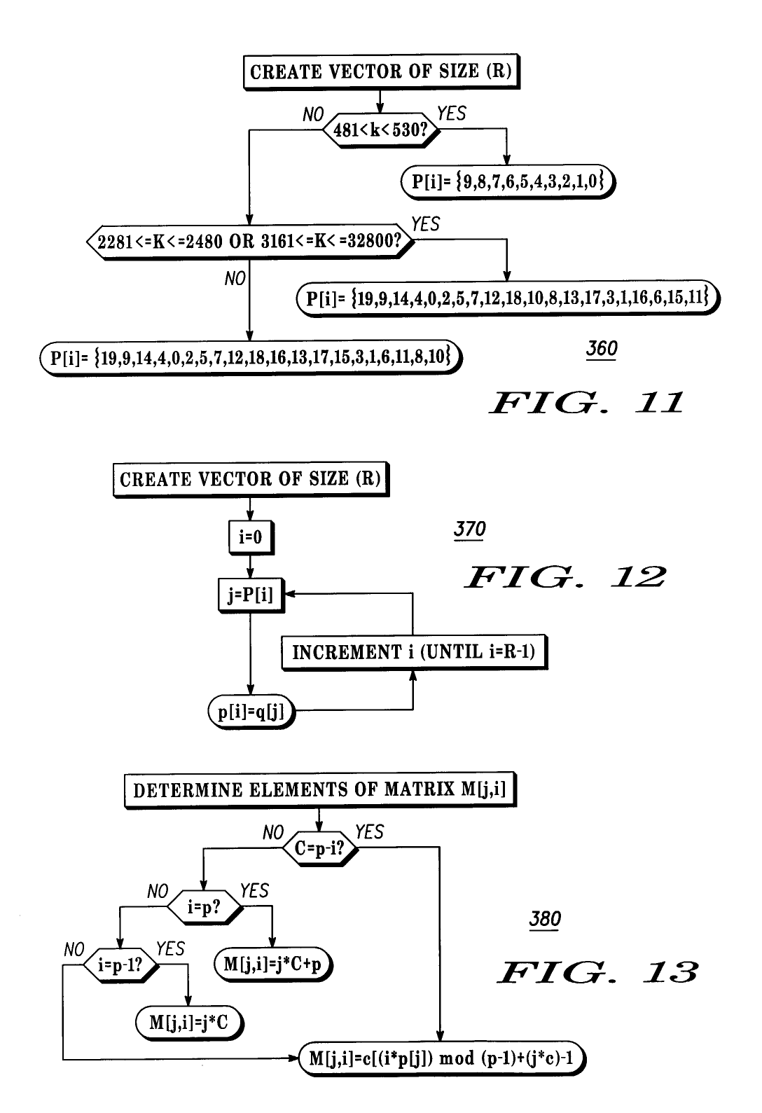

A vector, referred to as “c[i]” is generated according to the algorithm 340 shown in FIG. 9. A vector called q[i] is generated according to the algorithm 350 shown in FIG. 10. A vector referred to as P[i] is generated according to the algorithm 360 shown in FIG. 11 and a vector referred to as p[i] is generated according to the algorithm 370 shown in FIG. 12.

The elements of a matrix are determined according to the algorithm 380 shown in FIG. 13. At this point the system checks for the special case where K=C*R AND C=p+1. When this special case is detected, elements M[R−1,p] and M[R−1,0] are switched. There are 53 cases for 320 # K # 5114 where this occurs (one for each prime number p).

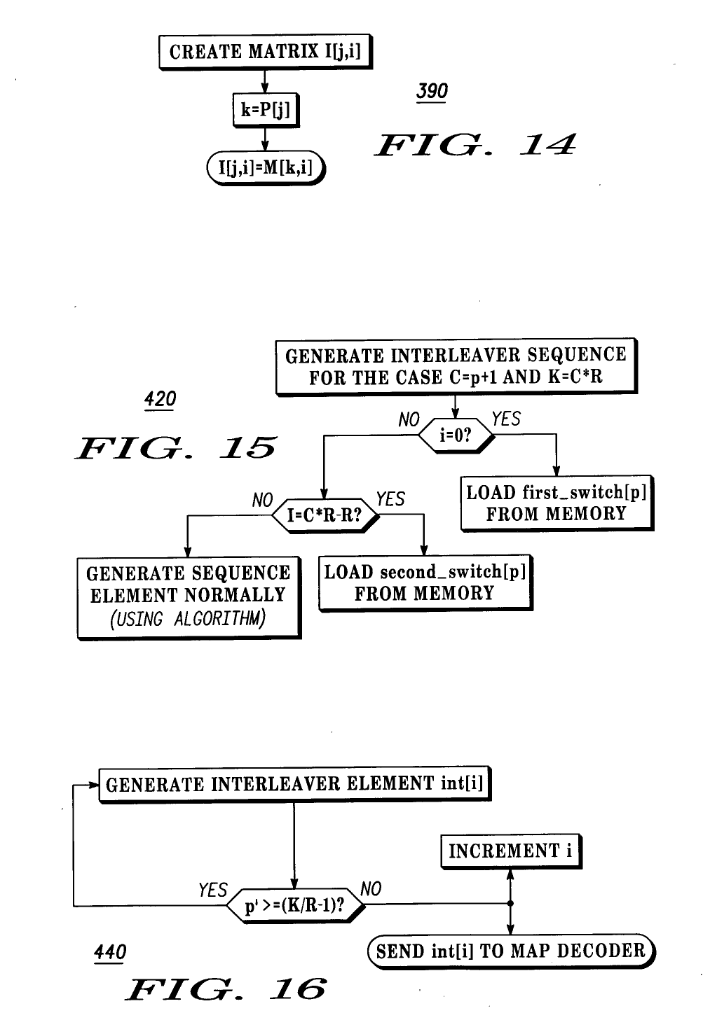

Next, the inter-row operations are performed to generate Matrix I[j,I]=M[P(j), I], according to the algorithm 390 shown in FIG. 14. The matrix is read out column-by-column to create a sequence of integers (e.g., int[0 . . . R−1], int[R . . . 2R−1] . . . int[CR−R . . . CR−1]) according to the following: int(k)=I[j+I*R]. If (int(k) ∃K) then int(k) must be removed from the sequence. A few alterations must be made to the algorithm as it is presented in the 3GPP specification in order for dynamic generation of the interleaver sequence to be feasible. These changes mainly change the structure and order of the algorithm but not its overall result.

The steps shown in FIGS. 12, 13 and 14 may be incorporated into one operation, which as long as the elements are produced in order (i.e. the first is produced first and the K'th is produced last, with K being the size of the interleaver block), will produce the same elements as if the matrix M[j, i] had been produced, the row operations of (1) and (4) had been performed, and the elements had been stripped from the matrix column by column. This can be seen in the code below:

| | |
|---|---|
| 1 | for(i = 0; i < c; i++) |
| 2 | { |
| 3 | for(j=0; j<R;j++) |
| 4 | { |

| | |
|---|---|
| 5 | if (i = = p) |

| | |
|---|---|
| 6 | i[j + i*R] = p + C*P(j); |

| | |
|---|---|
| 7 | else if (i = =0 p−1) |

| | |
|---|---|
| 8 | i[j + i*R] = C*P(j); |

| | |
|---|---|
| 9 | else { |

| | |
|---|---|
| 10 | i[j + i*R] = c(r[j]) + CP(j); |
| 11 | R[j] = (r[j] + q[j] mod (p−1) |

| | |
|---|---|
| 12 | } |
| 13 | } |

The above algorithm consists of two nested loops, one running throughout the columns of the matrix (which is not actually created), and the other handling the elements of each column. There are three cases for each particular column: one for if the current column is the last column of a interleaver in which C=p+1 (i=p); one for if it is the last column of an interleaver in which C=p or if it is the second-to-last column of one in which C=p+1 (i=p−1); and, finally, one for all other columns of all interleavers.

A few things can be seen from the code above. First, the vector p(j) is never generated, and thus the inter-row operation in the 3GPP specification is never performed. Thus the vector q[j] is used throughout, and the operation in (1) is ignored. The operation in (4), however, cannot be simply discarded; all terms in these rows, not just those containing p(i), are rearranged according to P(j). As seen in lines 6, 8, and 10 of the above code, this is accomplished by replacing the term ‘j’ of the proposed algorithm by ‘P(j)’ in the above code. Thus, the term that indicates which row is currently being referred to is permuted according to P(j) as these matrix elements are produced, not after the matrix has been assembled.

Another change regards the ‘−1’ term, which appears in matrix elements in the case where C=p−1, but missing in the above code. To avoid this term is added in preprocessing, during the generation of the c(i) vector. The vector elements c(i) become [c(i)−1] for this case.

The preprocessing modification of c(i) causes the interleaver element generation in columns through (p−2) to be the same for all cases \mathring{c}=p−1, C=p, C=p+1). From the 3GPP algorithm, these elements are found as:

M[j,i]=c([i*p(j)mod(p−1))+(j*C)

These elements are found in the above code in lines 10 and 11 as:

10 i[j+i*R]=c(r[j])+CP(j);

11 R[j]=(r[j]+q[j]mod (p−1)

The second right-hand-side term of line 10 is the same as the second term of the 3GPP specification term. In the second column, q(j) is used rather than p(j) to indicate the permutation and it's undoing. Also, the multiplication of the vector elements by the current column is eliminated by simply adding the quantity q(j) as each successive column is addressed, and storing it in the vector r(j), which is initialized to zeros. This is significant for two reasons. First, it replaces a multiply by a quicker add in the time-crucial Dynamic Stage. Second, it allows the preprocessing modification below to be possible.

As seen above, the algorithm's necessary, modulo function is performed on the r(j)accumulation vector, which is initially set to zero. In the 3GPP algorithm, the multiplication of the element by the p(j) term (which is simply the q(j) term in row-permuted form) can necessitate nearly 100 subtracts followed by checks to accomplish the modulo. The replacement of the multiplications by the above accumulation reduces the number of subtracts necessary to accomplish these modules by, in some cases, nearly a factor of twenty.

The computational intensity can be further reduced by accomplishing this modulo in the Preprocessing Stage, during the generation of the g(j) matrix. The modulo in the r(i) vector computation of line 11 of the code involves the current value of r(j), which is already modulo (p−1), and the q(j) term of the current element. The q(j)value can be replaced by a value that is already module (p−1):

q[j]=q[j]mod(p−1)

Line 11 of the code equivalently becomes:

11 r[j]=(r[j]+g[j])mod(p−1);

Since both terms are already mod(p−1), there is, at most, one subtraction to accomplish the module operation. Thus, line 11 becomes:

11 r[j]+=q[j];

The 3GPP algorithm is separated by the invention into a Preprocessing Stage and a Dynamic Stage. In other words. constants R, G and p, and vectors c(i), q(i) and P(i) must be generated and stored in memory before any interleaver elements can be generated. These constants and vectors are then used to produce the elements dynamically.

The operation that must be performed in this case is based on the existence of the matrix M[j,i]. The element in the lower-left comer is switched with the element in the lower right comer. Since this switch occurs in the 3GPP algorithm before the final row permutation, yet in this algorithm that permutation occurs dynamically, this permutation must be taken into account. According to the sequence P(j), the last element of each row always becomes the first element irrespective which of the three possible P(j)'s is being used. Thus, in this algorithm, the element corresponding to the upper-right corner must be switched with that of the upper-left comer. This switch is impossible if the interleaver elements are to be passed dynamically to the MAP decoder, soon as they are produced.

However, since this case occurs in only 53 cases (one for each possible p) for K values between 40 and 5114, these values can be stored in a lookup table. Thus, four vectors of size 53 must be accessible to the algorithm: the prime numbers, the corresponding primitive roots and the corresponding first and (K-R)th element. At those elements, if the special case conditions hold, the stored value is used rather than a computed value.

Since the created elements do not need to be used as place-holders in the matrix, values that are too big can be pruned out immediately, rather than waiting for the end of the algorithm. A simple compare can accomplish this pruning, with elements only being sent to the MAP if their value is less than (K−1).

If the interleaver sequence is to be generated dynamically, the interleaver generator must be coordinated with the MAP decoder. The sequence must be shuttled to the decoder as needed. Assuming the MAP needs one section of the interleaver at a time for interleaving/de-interleaving, that section is created and sent as needed. This eliminates the need to store tie entire sequence in memory, even though only one section is being used. With interleavers as large as 5000 scalars, the memory savings are significant.

The dynamic interleaver may be performed entirely in hardware. As shown above, the Interleaver Generator is divided into a Pre-processing Stage, where the necessary scalars and vectors are generated, and the Dynamic Stage, where the actual interleaver table elements are created. The MAP Decoder and the Preprocessing and Dynamic Stages of the Interleaver Generator may coexist in hardware on the same chip.

Once the matrix is created, then several special cases are accounted for, according to the algorithm 420 shown in FIG. 15. Then the individual interleaver elements are generated, according to the algorithm 440 shown in FIG. 16, and are sent to the MAP decoder as they are required.

The above described embodiments are given as illustrative examples only. It will be readily appreciated that many deviations may be made from the specific embodiments disclosed in this specification without departing from the invention. Accordingly, the scope of the invention is to be determined by the claims below rather than being limited to the specifically described embodiments above.

What is claimed is:

1. An apparatus for dynamic real time generation of interleaver sequences for a 3GPP decoder, comprising:
(a) a vector memory that stores at least a first vector, a second vector and a third vector, each vector corresponding to a desired reordering of a matrix;
(b) a data memory, including a plurality of memory locations, that stores individual data elements from a data stream so that each data element is stored in a different memory location in a predetermined order;
(c) an interleaver circuit, responsive to the first vector, the second vector and the third vector and responsive to a request signal, that dynamically generates plurality of interleaver elements, each interleaver element being generated in response to the request signal being asserted, each interleaver element having a value that is a function of the first vector, the second vector and the third vector, and each interleaver element pointing to a memory location;
(d) a MAP decoder that receives the interleaver elements from the interleaver circuit in a sequence and that retrieves the data element stored in the memory location pointed to by each interleaver element substantially as each interleaver element is received from the interleaver circuit, and that generates a reordered data stream comprising the data elements ordered in an arrangement corresponding to the sequence in which the interleaver elements are received from the interleaver circuit,
wherein the MAP decoder generates the request signal when a new interleaver element is required.

2. The apparatus of claim 1, wherein the first vector includes data corresponding to a reordering of rows in the matrix.

3. The apparatus of claim 2, wherein the second vector includes data corresponding to a reordering of columns in the matrix.

4. The apparatus of claim 1, wherein the values of the of the first vector, the second vector and the third vector are chose according to a 3GPP specification for generating a look up table.

5. A method of decoding a data stream, including a plurality of data elements, comprising the steps of:
(a) determining a value for a first vector, a second vector and a third vector, according to a 3GPP specification;
(b) generating a plurality of interleaver elements in a sequence, each interleaver element generated in response to a request signal as a function of the first vector, the second vector and the third vector and each interleaver element pointing to a memory location that stores a data element that is part of a data stream;
(c) retrieving the data element stored in the memory location pointed to by each interleaver element in the sequence that the interleaver elements are generated; and
(d) adding each data element to a reordered data stream as each interleaver element is received from its corresponding memory location.

6. A program for decoding a data stream, including a plurality of data elements, comprising the steps of:
(a) programming for determining a value for a first vector, a second vector and a third vector, according to a 3GPP specification;
(b) programming for generating a plurality of interleaver elements in a sequence, each interleaver element generated in response to a request signal as a function of the first vector, the second vector and the third vector and each interleaver element pointing to a memory location that stores a data element that is part of a data stream;
(c) programming for retrieving the data element stored in the memory location pointed to by each interleaver element in the sequence that the interleaver elements are generated; and
(d) programming for adding each data element to a reordered data stream as each interleaver element is received from its corresponding memory location.
